(19) United States
(12) Patent Application Publication
(10) Pub. No.: US 2025/0343054 A1
(43) Pub. Date: Nov. 6, 2025

(54) SUBSTRATE PROCESSING APPARATUS, GAS SUPPLY SYSTEM, METHOD OF PROCESSING SUBSTRATE, METHOD OF MANUFACTURING SEMICONDUCTOR DEVICE, AND RECORDING MEDIUM

(71) Applicant: KOKUSAI ELECTRIC CORPORATION, Tokyo (JP)

(72) Inventor: Hidehiro YANAI, Toyama-shi (JP)

(73) Assignee: KOKUSAI ELECTRIC CORPORATION, Tokyo (JP)

(21) Appl. No.: 19/268,834

(22) Filed: Jul. 14, 2025

Related U.S. Application Data
(63) Continuation of application No. PCT/JP2023/010697, filed on Mar. 17, 2023.

(51) Int. Cl. H01L 21/67; G05D 7/06

(52) U.S. Cl. CPC H01L 21/67017; G05D 7/0652

(57) ABSTRACT

A technique includes: a first valve controlling the emission of gas from the first nozzle, that is installed in a first flow path connecting a first gas supply source and a first nozzle; a second valve controlling the emission of gas from the second nozzle, that is installed in a second flow path connecting a second gas supply source and a second nozzle; a third valve controlling the emission of the gas from the second nozzle, that is installed in a third flow path; and a fourth valve controlling the emission of the gas from the first nozzle, that is installed in a fourth flow path, wherein a difference between the average of the conductance of the first and the fourth valve and the average of the conductance of the second and the third valve is smaller than a difference between the conductance of the first and the second valve.

### CROSS-REFERENCE TO RELATED APPLICATION

This application is a Bypass Continuation Application of PCT International Application No. PCT/JP2023/010697, filed on Mar. 17, 2023, the disclosure of which is incorporated herein in its entirety by reference.

### TECHNICAL FIELD

The present disclosure relates to a substrate processing apparatus, a gas supply system, a method of processing a substrate, a method of manufacturing a semiconductor device, and a recording medium.

### BACKGROUND

In the prior art, a semiconductor manufacturing apparatus for manufacturing semiconductor devices is known as an example of a substrate processing apparatus. As an example of the semiconductor manufacturing apparatus, a vertical apparatus that processes a plurality of substrates (hereinafter also referred to as “wafers”) while holding them in multiple stages in a vertical direction is known in the related art.

In the related art, a raw material gas is supplied into a process chamber through two pipe systems. That is, a tank is installed for each pipe, and valves are installed on the upstream side and downstream side of the tank, respectively, and the raw material gas is controlled so as to alternately accumulate in the tank and release into the process chamber.

When a gas is supplied into the process chamber, the flow rate and flow velocity of the gas in the process chamber vary due to variations in the conductance of the valves installed in the pipe, so there is a possibility that sufficient reproducibility cannot be obtained for substrate processing such as film formation.

### SUMMARY

The present disclosure is made in consideration of the above, and provides a technique capable of eliminating the decrease in reproducibility of substrate processing due to differences in valve conductance.

According to embodiments of the present disclosure, a technique includes: a first valve installed in a first flow path connecting a first gas supply source and a first nozzle that emits a gas into a process chamber, the first valve controlling the emission of the gas from the first nozzle; a second valve installed in a second flow path connecting a second gas supply source and a second nozzle that emits a gas into the process chamber, the second valve controlling the emission of the gas from the second nozzle; a third valve installed in a third flow path connecting an upstream side of the first valve in the first flow path and a downstream side of the second valve in the second flow path, the third valve controlling the emission of the gas from the second nozzle; and a fourth valve installed in a fourth flow path connecting an upstream side of the second valve in the second flow path and a downstream side of the first valve in the first flow path, the fourth valve controlling the emission of the gas from the first nozzle, wherein the substrate processing apparatus is configured so that a difference between the average of a conductance of the first valve and a conductance of the fourth valve and the average of a conductance of the second valve and a conductance of the third valve is smaller than a difference between the conductance of the first valve and the conductance of the second valve.

### BRIEF DESCRIPTION OF DRAWINGS

The accompanying drawings, which are incorporated in and constitute a part of the specification, illustrate embodiments of the present disclosure.

FIG. 1 is a schematic diagram showing the schematic configuration of a substrate processing apparatus according to an embodiment of the present disclosure.

FIG. 2 is a schematic configuration diagram showing a controller of the substrate processing apparatus according to the embodiment of the present disclosure, in which a control system of the controller is shown in a block diagram.

FIG. 3 is a time chart showing an example of the timing of opening/closing of each valve in the substrate processing apparatus according to the embodiment of the present disclosure.

FIG. 4 is a conceptual diagram showing an example of a method of selecting each valve.

FIG. 5 is a conceptual diagram showing another example of the method of selecting each valve.

FIG. 6 is a schematic diagram showing the schematic configuration of a substrate processing apparatus according to another embodiment of the present disclosure.

FIG. 7 is a schematic cross-sectional view of a modified valve structure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components are not described in detail so as not to obscure aspects of the various embodiments.

### Structure of Substrate Processing Apparatus

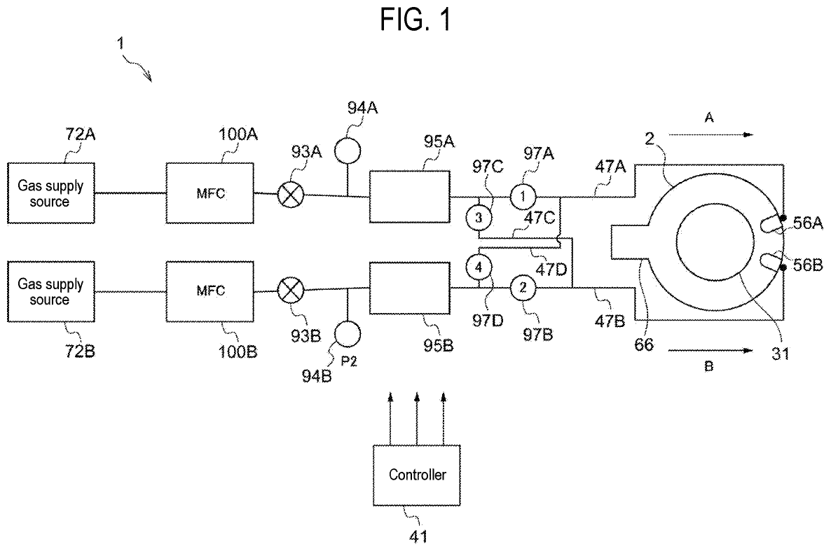

FIG. 1 is a schematic diagram showing the schematic configuration of a substrate processing apparatus 1 according to an embodiment of the present disclosure. Note that the drawings used in the following description are schematic, and the dimensional relationship, ratios, and the like of various elements shown in the drawings do not always match the actual ones. Further, the dimensional relationship, ratios, and the like of various elements between plural figures do not always match each other.

Two nozzles that emit a gas into a process chamber 2 into which a substrate 31 is loaded and processed, namely, a first nozzle 56A and a second nozzle 56B, are installed in the process chamber 2. The gas is supplied to the first nozzle 56A from a gas supply source (i.e., a first gas supply source) 72A, and to the second nozzle 56B from a gas supply source (i.e., a second gas supply source) 72B. A gas flow path from the gas supply source 72A to the first nozzle 56A is a first flow path 47A. A gas flow path from the gas supply source 72B to the second nozzle 56B is a second flow path 47B. In the figure, arrows with “A” and “B” indicate the directions of gas flow in the first flow path 47A and the second flow path 47B, respectively. The gas supply sources 72A and 72B may be a single supply source. The gas supply sources 72A and 72B may be the same type of gas supply sources or different types of gas supply sources. On the other hand, an exhaust duct 66 for exhausting a processed gas is installed on the downstream side of the process chamber 2.

The process chamber 2 can be configured as a reaction tube in a vertical furnace apparatus. In this case, a plurality of substrates 31 are arranged in multiple stages in the process chamber, and the first nozzle 56A and the second nozzle 56B can inject the gas from the side of the substrates 31 so as to form a gas flow parallel to the surface of each substrate 31. The first nozzle 56A and the second nozzle 56B can be configured to be plane-symmetrical with respect to a certain plane that is perpendicular to the substrate 31 and passes through the center of the substrate 31, as an example. The process chamber can be depressurized to 100 Pa or less by a vacuum pump connected to the exhaust duct 66.

In the first flow path 47A, a mass flow controller (hereinafter abbreviated as an “MFC”) 100A, an accumulation valve 93A, a first buffer tank 95A, and a first valve 97A are installed in series in this order from the gas supply source 72A at the most upstream position to the first nozzle 56A at the most downstream position. A pressure sensor 94A is installed in a flow path between the accumulation valve 93A and the first buffer tank 95A. In the second flow path 47B, an MFC 100B, an accumulation valve 93B, a second buffer tank 95B, and a second valve 97B are installed in series in this order from the gas supply source 72B at the most upstream position to the second nozzle 56B at the most downstream position. A pressure sensor 94B is installed in a flow path between the accumulation valve 93B and the second buffer tank 95B.

That is, the first valve 97A is installed in the first flow path 47A connecting the gas supply source 72A and the first nozzle 56A that emits the gas into the process chamber 2, and controls the emission of the gas from the first nozzle 56A. The second valve 97B is installed in the second flow path 47B connecting the gas supply source 72B and the second nozzle 56B that emits the gas into the process chamber 2, and controls the emission of the gas from the second nozzle 56B. The length and conductance from the gas supply source 72A to the first nozzle 56A in the first flow path 47A may be equal to the length and conductance from the gas supply source 72B to the second nozzle 56B in the second flow path 47B, respectively, but are not limited thereto. The gas supplied from the gas supply sources 72A and 72B may be a raw material gas, an inert gas, or a carrier gas.

Further, a third valve 97C is installed in a third flow path 47C as a bypass connecting the first flow path 47A on the upstream of the first valve 97A and the second flow path 47B on the downstream of the second valve 97B. This third valve 97C controls the gas emission from the upstream side of the first valve 97A in the first flow path 47A to the second nozzle 56B. The first buffer tank 95A is installed on the upstream side of a branch point (i.e., the third flow path 47C) of the first flow path 47A to the third valve 97C. On the other hand, a fourth valve 97D is installed in a fourth flow path 47D as a bypass connecting the second flow path 47B on the upstream of the second valve 97B and the first flow path 47A on the downstream of the first valve 97A. This fourth valve 97D controls the gas emission from the upstream side of the second valve 97B in the second flow path 47B to the first nozzle 56A. The second buffer tank 95B is installed on the upstream side of a branch point (i.e., the fourth flow path 47D) of the second flow path 47B to the fourth valve 97D. The first valve 97A to the fourth valve 97D are installed on the most downstream side among a plurality of valves including the accumulation valves 93A and 93B installed between the gas supply sources 72A and 72B and the first nozzle 56A and second nozzle 56B, and are also called final valves. As a result, the relationship between each nozzle and the flow path is not fixed but can be switched appropriately, and as a result, the amount of gas supplied to the process chamber 2 from each flow path is equalized.

Then, the first valve 97A to the fourth valve 97D are selected so that a difference between the average conductance of the first valve 97A and the fourth valve 97D and the average conductance of the second valve 97B and the third valve 97C is smaller than a difference between the conductance of the first valve 97A and the conductance of the second valve 97B. Conductance refers to the conductance of a flow path in a valve when the valve is opened. For example, assuming that the pipe conductance of the first flow path 47A is equal to and the pipe conductance of the second flow path 47B, if solely the first valve 97A and the second valve 97B are installed, the difference in conductance between the first valve 97A and the second valve 97B will appear as a difference in the flow rate or flow velocity between gases emitted from the first nozzle 56A and the second nozzle 56B. In order to alleviate this, by providing the third valve 97C and the fourth valve 97D selected as described above in the third flow path 47C and the fourth flow path 47D as bypasses between the first flow path 47A and the second flow path 47B, respectively, it is expected that a difference in amount between gases emitted from the first nozzle 56A and the second nozzle 56B will be leveled out.

The configuration from the gas supply sources 72A and 72B to the first nozzle 56A and the second nozzle 56B may have symmetry, but is not limited thereto. The third flow path 47C and the fourth flow path 47D may be arranged to intersect three-dimensionally without communicating with each other, and may be designed to have substantially equal conductance as a flow path, but are not limited thereto.

The first buffer tank 95A and the second buffer tank 95B have substantially equal volumes and accumulate a gas sent from the gas supply sources 72A and 72B by the MFCs 100A and 100B, respectively. By emitting the gas in a time shorter than the accumulation time, a pulsed supply of a large flow rate called a flash flow is performed, so that the surface of the substrate 31 is uniformly exposed to the gas. This is often useful in a hot-wall type process chamber involving a gas phase reaction, in order to perform a film forming process with good uniformity and step coverage on the substrate 31 on which a pattern such as a deep groove with a width smaller than the mean free path of the gas is formed. For this reason, it may be preferable that the flash flow supply is performed with an error of 1% or less from the standard flow rate or flow velocity.

When the accumulation valves 93A and 93B are opened, a gas with its mass flow rate controlled to a constant value flows from the MFCs 100A and 100B into the first buffer tank 95A and the second buffer tank 95B, respectively. When the gas accumulates in the first buffer tank 95A and the second buffer tank 95B, the pressure sensors 94A and 94B detect a pressure rise in the respective flow paths. Upon detecting this pressure rise, a controller 41, which will be described later, closes the accumulation valves 93A and 93B, thereby stopping the flow of gas into the first buffer tank 95A and the second buffer tank 95B.

The gas accumulated in the first buffer tank 95A is emitted from the first nozzle 56A into the process chamber 2 through the first flow path 47A by opening the first valve 97A, or is emitted from the second nozzle 56B into the process chamber 2 through the third flow path 47C and the second flow path 47B by opening the third valve 97C. On the other hand, the gas accumulated in the second buffer tank 95B is emitted from the second nozzle 56B into the process chamber 2 through the second flow path 47B by opening the second valve 97B, or is emitted from the first nozzle 56A into the process chamber 2 through the fourth flow path 47D and the first flow path 47A by opening the fourth valve 97D.

Here, for example, if the conductances of four valves are different from each other, when the valve with the highest conductance is the first valve 97A, the valve with the lowest conductance is the fourth valve 97D, and the remaining two valves are the second valve 97B and the third valve 97C, the difference between the average conductance of the first valve 97A and the fourth valve 97D and the average conductance of the second valve 97B and the third valve 97C will always be smaller than the difference between the conductance of the first valve 97A and the conductance of the second valve 97B. At this time, the conductance of the first valve 97A is greater than the arithmetic average of the conductances of the first valve 97A to the fourth valve 97D, and the conductance of the fourth valve 97D is smaller than the arithmetic average. The conductance of one of the second valve 97B and the third valve 97C may be greater than the arithmetic average, and the conductance of the other may be smaller than the arithmetic average, but this is not limited thereto. At least one selected from the group of a set of the first valve 97A and the second valve 97B and a set of the third valve 97C and the fourth valve 97D may be an opening/closing valve, but this is not limited thereto. Alternatively, at least one selected from the group of the set of the first valve 97A and the second valve 97B and the set of the third valve 97C and the fourth valve 97D may be a conductance valve whose opening degree can be varied, and the conductance valve may constitute a part of the MFC. Even if the apparatus includes a valve whose opening degree cannot be varied, it is expected that the difference in the amount between gases emitted from the first nozzle 56A and the second nozzle 56B can be leveled out.

### Controller

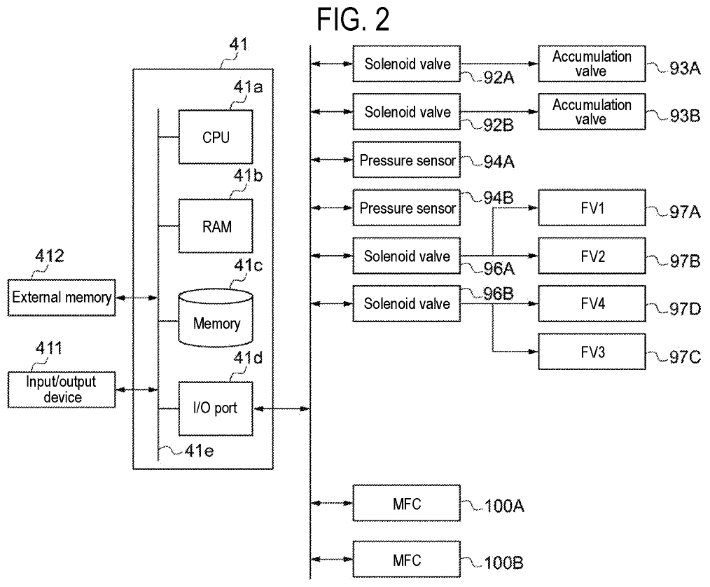

The substrate processing apparatus 1 also includes a controller 41 that controls the operation of each part. The controller 41 is schematically shown in FIG. 2. The controller 41, which is a control part (control means), is configured as a computer including a CPU (Central Processing Unit) 41a, a RAM (Random Access Memory) 41b, a memory 41c, and an I/O port 41d. The RAM 41b, the memory 41c, and the I/O port 41d are configured to be capable of exchanging data with the CPU 41a via an internal bus 41e. The controller 41 is configured to be capable of connecting to an input/output device 411 configured as, e.g., a touch panel, or an external memory 412.

The memory 41c is configured with, for example, a flash memory, a HDD (Hard Disk Drive), etc. A control program for controlling the operations of the substrate processing apparatus 1, a process recipe in which the procedures and conditions of substrate processing are written, a correction recipe, etc. are readably stored in the memory 41c. In addition, the RAM 41b is configured as a memory area (work area) in which programs, data, etc. read by the CPU 41a are temporarily stored.

The I/O port 41d is connected to the above-mentioned pressure sensors 94A and 94B and MFCs 100A and 100B, as well as to solenoid valves 92A and 92B for opening/closing the accumulation valves 93A and 93B, a solenoid valve 96A for opening/closing the first valve 97A and the second valve 97B, and a solenoid valve 96B for opening/closing the third valve 97C and the fourth valve 97D. The first valve 97A to the fourth valve 97D may be configured as pneumatic valves. The first valve 97A and the second valve 97B may be configured to be opened/closed in conjunction with each other by a working fluid controlled by the solenoid valve 96A, and the third valve 97C and the fourth valve 97D may be configured to be opened/closed in conjunction with each other by a working fluid controlled by the solenoid valve 96B. With this configuration, the influence of variations in the operating speed of the solenoid valves can be reduced as compared to when the solenoid valves are installed individually. In addition, if the gas emission from the first nozzle 56A and the second nozzle 56B is not performed simultaneously, it is needed to install corresponding solenoid valves for the first valve 97A to the fourth valve 97D.

The controller 41 controls the accumulation valve 93A, the first valve 97A, the third valve 97C, and the accumulation valve 93B, the second valve 97B, and the fourth valve 97D so as to alternately repeat the accumulation of the gas in the first buffer tank 95A and the second buffer tank 95B and the emission of the gas from the first buffer tank 95A and the second buffer tank 95B.

The controller 41 is not limited to being configured as a dedicated computer, but may be configured as a general-purpose computer. For example, the controller 41 according to this embodiment can be configured by preparing the external memory 412 (for example, a semiconductor memory such as a USB memory or a memory card) in which the above-mentioned program is stored, and installing the program in a general-purpose computer using such the external memory 412. The means for supplying the program to the computer is not limited to supplying it via the external memory 412. For example, the program may be supplied without going through the external memory 412 by using a communication means such as the Internet or a dedicated line. The storage device 41c and the external memory 412 are configured as computer-readable recording media. Hereinafter, these are collectively referred to simply as recording media. In the present disclosure, when the term “recording medium” is used, it may include the storage device 41c alone, the external memory 412 alone, or both.

### Opening/Closing Timing of Each Valve

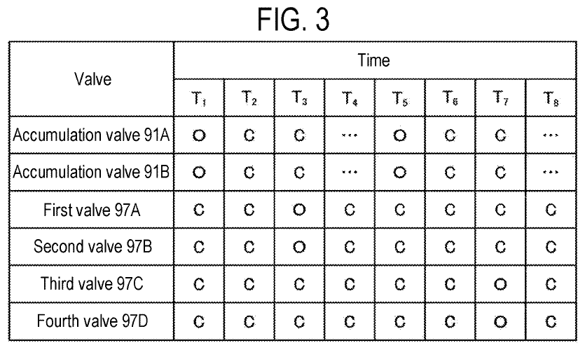

Next, the opening/closing timing of each valve in the substrate processing apparatus 1 of this embodiment will be described with reference to a time chart of FIG. 3. In FIG. 3, “O” indicates a state in which the valve is opened, “C” indicates a state in which the valve is closed, and “ . . . ” indicates any state.

First, at time T₁, the accumulation valves 93A and 93B are opened to accumulate a gas in the buffer tanks 95A and 95B. Then, at time T₂, the accumulation valves 93A and 93B are closed to maintain the state of accumulation of the gas at a predetermined pressure. Then, at time T₃, in a state in which both the buffer tanks 95A and 95B are filled with the gas, when the controller 41 opens the first valve 97A and the second valve 97B while closing the third valve 97C and the fourth valve 97D, the gas accumulated in the buffer tank 95A passes through the first valve 97A and the first flow path 47A and is emitted from the first nozzle 56A into the process chamber 2, and at the same time, the gas accumulated in the buffer tank 95B passes through the second valve 97B and the second flow path 47B and is emitted from the second nozzle 56B into the process chamber 2. Note that the emission of gas from the first nozzle 56A and the emission of gas from the second nozzle 56B do not need to be simultaneous, and there may be an appropriate time difference (same below). Then, at time T₄, the first valve 97A to the fourth valve 97D are closed, and the process chamber 2 is exhausted. At this time, a purge gas or other film forming gas may be supplied from another supply system (not shown).

Next, at time T₅, the accumulation valve 93A and the accumulation valve 93B are opened to accumulate a gas in the buffer tanks 95A and 95B. Then, at time T₆, the accumulation valve 93A and the accumulation valve 93B are closed to maintain the state of accumulation of the gas at a predetermined pressure. Then, at time T₇, in a state in which both the buffer tank 95A and the buffer tank 95B are filled with the gas again, when the controller 41 opens the third valve 97C and the fourth valve 97D while closing the first valve 97A and the second valve 97B, the gas accumulated in the buffer tank 95A passes through the third valve 97C, the third flow path 47C, and the second flow path 47B and is emitted from the second nozzle 56B into the process chamber 2, and at the same time, the gas accumulated in the buffer tank 95B passes through the fourth valve 97D, the fourth flow path 47D, and the first flow path 47A and is emitted from the first nozzle 56A into the process chamber 2. Time T₈ is the same as time T₄.

That is, the controller 41 included in the substrate processing apparatus 1 of this embodiment is configured to be capable of controlling the first valve 97A and the third valve 97C to be opened alternatively when a predetermined amount of gas is accumulated in the first buffer tank 95A, and the second valve 97B and the fourth valve 97D to be opened alternatively when a predetermined amount of gas is accumulated in the second buffer tank 95B. The controller 41 is also configured to be capable of controlling the first valve 97A and the fourth valve 97D to be opened at a predetermined frequency, for example, alternately, and the second valve 97B and the third valve 97C to be opened at a predetermined frequency, for example, alternately. With this configuration, both the gas accumulated in the first buffer tank 95A and the gas accumulated in the second buffer tank 95B are emitted to the process chamber 2 alternately via the first flow path 47A and the second flow path 47B.

By performing a series of operations from time T₁ to time T₈ one or more times, the substrate 31 is exposed to the gas to achieve substrate processing such as film formation. Furthermore, the series of operations can be repeated multiple times while the substrate 31 is being rotated. In this case, if a first process from time T₁ to time T₄ and a second process from time T₅ to time T₈ are simply performed alternately, the first process and the second process can be performed with the same frequency. If the first process and the second process are performed in a ratio of n₁:n₂ (where n₁ and n₂ are natural numbers), respectively, their frequencies can be made different. For example, if the second process is omitted once in 100 times, the frequency ratio is 100:99. When one of the first process and the second process is omitted, the other process may be performed consecutively by dispersing two consecutive processes rather than performing the other process three or more times consecutively, but this is not limited thereto.

### Selection of Each Valve

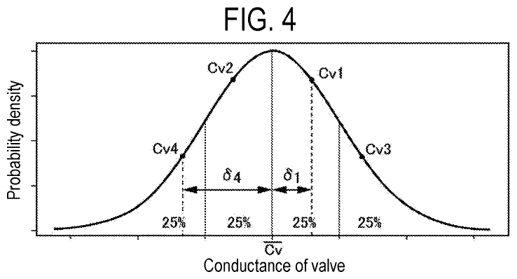

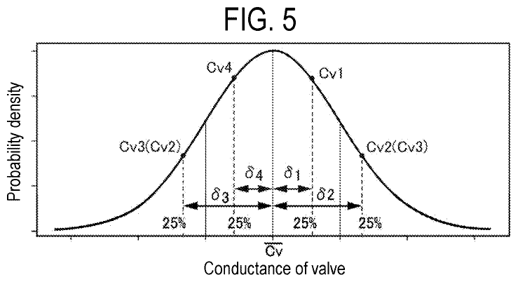

Here, an example in which the first valve 97A to the fourth valve 97D are selected from a group of valves including four or more valves obtained from a manufacturer will be described with reference to FIGS. 4 and 5. Here, as a premise of the description, it is assumed that the valves have a specified numerical range of conductance, and the conductance of each valve follows the normal distribution shown in FIGS. 4 and 5. In FIGS. 4 and 5, the horizontal axis represents the value of conductance centered on the average value indicated by Cv bar, and the vertical axis represents the occurrence probability of each conductance. As can be seen from both figures, the occurrence probability of the average conductance is the highest, and as the conductance increases or decreases from the average conductance, the occurrence probability decreases. Vertical lines in each figure divide the area of the probability density into four equal regions centered on the average conductance. The four regions divided by these vertical lines are designated as a first region, a second region, a third region, and a fourth region, respectively, from the high probability side. Cv1, Cv2, Cv3, and Cv4 in the figures are the conductances of the first valve 97A, the second valve 97B, the third valve 97C, and the fourth valve 97D, respectively.

In FIG. 4, Cv1 is selected from the second region, Cv2 from the third region, Cv3 from the first region, and Cv4 from the fourth region. By selecting in this manner, the allowable variation is distributed to a plurality of substrate processing apparatuses, so that uneven distribution of variation between the apparatuses is reduced. Here, the combined conductance (Cv1*4) of the first valve 97A and the fourth valve 97D is defined by the following equation 1, where p1 is the frequency at which the first valve 97A is opened.

$$Cv 1 * 4 = p 1 \cdot Cv 1 + ( 1 - p 1 ) \cdot Cv 4 \qquad ( Equation 1 )$$

In addition, the combined conductance (Cv2*3) of the second valve 97B and the third valve 97C is also defined by the following equation 2, where p2 is the frequency at which the second valve 97B is opened.

$$Cv 2 * 3 = p 2 \cdot Cv 2 + ( 1 - p 2 ) \cdot Cv 3 \qquad ( Equation 2 )$$

Here, the frequency of opening can be defined as the ratio of the number of times that a valve of interest is opened to the total number of times that a plurality of valves for supplying a gas to the same nozzle are opened, and the combined conductance can be said to be the sum of values obtained by weighting the conductance of each valve by the frequency at which each valve is opened. That is, by selecting the conductance of each valve as shown in FIG. 4, each of the set of the first valve 97A and the fourth valve 97D and the set of the second valve 97B and the third valve 97C can be regarded as a single valve with a substantially average conductance.

According to the configuration of FIG. 4, by selecting valves so that the values of Cv3-Cv2 and Cv1-Cv4 are approximated, the degree of variation in the emission of gas from the first nozzle 56A and the emission of gas from the second nozzle 56B can be made uniform, which provides the excellent symmetry of the variation. By selecting valves so that the variation of Cv3-Cv2 and Cv1-Cv4 falls within a predetermined range between the plurality of substrate processing apparatuses, reproducibility can be improved. In addition, in order to further improve the reproducibility of substrate processing, the frequency can be set as follows. That is, of the first valve 97A and the fourth valve 97D which flow the gas into the same first flow path 47A, the ratio (i.e., p1:p4) of the frequency (p1) at which the first valve 97A, which has a conductance (Cv1) closer to the average value, is opened to the frequency (p4) at which the fourth valve 97D, which has a conductance (Cv4) farther from the average value, is opened, may be set as the ratio (i.e., δ4:δ1) of the absolute value (δ4 in the figure) of the deviation (i.e., the distance from the average value) of the conductance (Cv4) of the fourth valve 97D to the absolute value (δ1 in the figure) of the deviation of the conductance (Cv1) of the first valve 97A. In actuality, the ratio may be set as an integer value approximating this ratio (for example, 5:2), but this is not limited thereto. That is, in the example shown in the figure, the first process frequency at which the first valve 97A is opened is set to 2.5 times the second process frequency at which the fourth valve 97D is opened, thereby making it possible to bring the combined conductance of the first valve 97A and the fourth valve 97D closer to the average value.

On the other hand, in FIG. 5, Cv1 is selected from the second region, Cv2 (or Cv3) from the first region, Cv3 (or Cv2) from the fourth region, and Cv4 from the third region. More preferably, the absolute value of the deviation δ1 of the conductance (Cv1) of the first valve 97A and the absolute value of the deviation δ4 of the conductance (Cv4) of the fourth valve 97D are selected to be close to each other, and similarly, the absolute value of the deviation δ2 of the conductance (Cv2) of the second valve 97B and the absolute value of the deviation δ3 of the conductance (Cv3) of the third valve 97C are selected to be close to each other. In this case, of the first valve 97A and the fourth valve 97D which flow the gas into the same first flow path 47A, the ratio (i.e., F1:F4) of the frequency (F1) at which the first valve 97A is opened to the frequency (F4) at which the fourth valve 97D is opened may be set as the ratio (i.e., δ4:δ1≐1:1) of the absolute value of the deviation of the conductance (Cv4) of the fourth valve 97D to the absolute value of the deviation of the conductance (Cv1) of the first valve 97A, but this is not limited thereto. In other words, in the example shown in the figure, the first valve 97A and the fourth valve 97D are alternately opened with the same frequency, so that the combined conductance of the first valve 97A and the fourth valve 97D can be made to approach the average value. Here, even when the frequency at which the first valve 97A is opened is p1 (½ in the example shown in this figure), the combined conductance (Cv1*4) of the first valve 97A and the fourth valve 97D is defined in the same way by the above equation 1. In addition, when the probability with which the second valve 97B is opened is p2 (½ in the example shown in this figure), the combined conductance (Cv2*3) of the second valve 97B and the third valve 97C is also defined in the same way by the above equation 2.

In the example shown in FIG. 5, it can be said that the first valve 97A and the fourth valve 97D are selected from among four or more valves including the first valve 97A to the fourth valve 97D such that the fourth valve 97D has a conductance closest to a value obtained by inverting the sign of the deviation of the conductance of the first valve 97A, and the second valve 97B and the third valve 97C are selected from among the four or more valves excluding the first valve 97A and the fourth valve 97D such that the third valve 97C has a conductance closest to a value obtained by inverting the sign of the deviation of the conductance of the second valve 97B. In other words, the first valve 97A and the fourth valve 97D are selected from among N valves (where, N is an integer equal to or greater than 4) including the first valve 97A to the fourth valve 97D, as valves corresponding to n valves before and n valves after (where, n≤N/2) from the median when the N valves are sorted by conductance, and the second valve 97B and the third valve 97C are selected from among the N valves, as valves corresponding to m valves before and m valves after (where, m≤N/2) from the median.

By selecting the conductance of each valve in this manner, each of the set of the first valve 97A and the fourth valve 97D and the set of the second valve 97B and the third valve 97C can be regarded as a single valve with a substantially average conductance, and as a result, the amount of gas supplied from each nozzle can be equalized.

According to the configuration of FIG. 5, valves are selected so that the difference in conductance (i.e., Cv2-Cv1 and Cv4-Cv3) between the valves opened at the same time is approximated, so that the relationship between the strength of the emission from the first nozzle 56A and the strength of the emission from the second nozzle 56B can be inverted or kept constant, resulting in excellent temporal symmetry. Then, by selecting valves so that the difference in conductance between these falls within a predetermined range between a plurality of substrate processing apparatuses, reproducibility can be improved. Note that an unbalance in the strength (flow rate or flow velocity) of the emission from the nozzles can cause a vortex to occur in the process chamber 2, and the state of the vortex can affect the in-plane uniformity of the processing and the gas exhaust time. In this example, when Cv2 is selected from the first region, the strength of the emission from the first nozzle 56A and the second nozzle 56B is inverted between the first process and the second process, and the state of the vortex becomes similar while the rotation direction of the vortex is inverted. On the other hand, when Cv2 is selected from the fourth region, the difference in the strength of the emission from each nozzle is almost constant, and therefore, the state of the vortex becomes similar too.

Note that the valve selection method shown in FIGS. 4 and 5 is merely an example and is not limited thereto. For example, Cv1 and Cv3 (or Cv2) can be selected from the first or second region so as to be as similar to each other as possible, and Cv4 and Cv2 (or Cv3) can be selected from the third or fourth region so that the polarity of the deviation is opposite to that of Cv1, the absolute value of the deviation is as close as possible to Cv1, and they are as similar to each other as possible. The valves that are as similar as possible can be selected as the valves corresponding to two adjacent valves when a group of valves including a number of valves sufficiently larger than four is sorted in order of conductance. As a result, the symmetry between the emission from the first nozzle 56A and the emission from the second nozzle 56B is good, the frequency of the first process and the frequency of the second process can be made 1:1, and further, when Cv1 and Cv2 are selected to be similar to each other, the generation of vortexes can be suppressed. Note that the variation in gas supply amount corresponding to the difference between Cv1 and Cv4 and the difference between Cv2 and Cv3 will vary between the apparatuses, but as long as the relationship between the gas supply amount (flow rate or flow velocity) and the film quality parameter (for example, film thickness) can be linearly approximated, this effect is limited.

In addition, the average value that serves as the standard for the deviation is not limited to the one calculated from a group of valves to be selected, and can be set arbitrarily. For example, one substrate processing apparatus with proven performance may be used as a master apparatus, and the average value of the four valves from the first valve 97A to the fourth valve 97D used in the master apparatus may always be used.

Those skilled in the art will understand that by selecting the first valve 97A to the fourth valve 97D as described above, the variation in the combined conductance is smaller than that of each individual valve. For example, if a coefficient of variation obtained by dividing the standard deviation o of the conductance of a group of valves by the average value is 0.02 and every valve within +20 is used, the maximum variation (i.e., a difference between the maximum and minimum) between Cv1 and Cv2 will be 8%. On the other hand, if the four valves are selected from a number of valves that is sufficiently greater than four, the variation in the combined conductance can be reduced to 1% or less.

### Relationship with Conductance of Flow Path

Here, as described above, the first flow path 47A and the second flow path 47B shown in FIG. 1 may have the same length and conductance, but in reality, they may differ. In that case, the first valve 97A to the fourth valve may be selected as follows.

First, assume that the pipe conductance of the first flow path 47A is Cp1 and the pipe conductance of the second flow path 47B is Cp2. At this time, in order to ensure a difference between the pipe conductance of the first flow path 47A (Cp1) and the pipe conductance of the second flow path 47B (Cp2), the relationship shown in the following equation 3 is needed to be established using the combined conductance of the first valve 97A and the fourth valve 97D (Cv1*4, see the above equation 1) and the combined conductance of the second valve 97B and the third valve 97C (Cv2*3, see the above equation 2).

$$2 / Cv 1 * 4 + 1 / Cp 1 = 2 / Cv 2 * 3 + 1 / Cp 2 \qquad ( Equation 3 )$$

The above equation 3 is transformed into the following equation 4.

$$2 / Cv 1 * 4 - 2 / Cv 2 * 3 = 1 / Cp 2 - 1 / Cp 1 \qquad ( Equation 4 )$$

Here, a difference between twice the reciprocal of the combined conductance of the first valve 97A and the fourth valve 97D and twice the reciprocal of the combined conductance of the second valve 97B and the third valve 97C may be set so as to compensate for the right-hand side of the above equation 4, i.e., a difference between the reciprocal of the conductance of the second flow path 47B and the reciprocal of the conductance of the first flow path 47A. Specifically, if the combined conductance of the first valve 97A and the fourth valve 97D and the combined conductance of the second valve 97B and the third valve 97C can be set so that the right-hand side of the above equation 4 is between 0 and 2×(1/Cp2-1/Cp1), the difference in conductance between the first flow path 47A and the second flow path 47B can be compensated for.

### Gas Supply System

The substrate processing apparatus (1) may also be regarded as a gas supply system including: (a) a first valve (97A) installed in a first flow path (47A) connecting a gas supply source (72A, 72B) and a first nozzle (56A) that emits a gas into a process chamber (2), the first valve (97A) controlling the emission of the gas from the first nozzle (56A); (b) a second valve (97B) installed in a second flow path (47B) connecting a gas supply source (72A, 72B) and a second nozzle (56B) that emits a gas into the process chamber (2), the second valve (97B) controlling the emission of the gas from the second nozzle (56B); (c) a third valve (97C) installed in a third flow path (47C) connecting the upstream side of the first valve (97A) in the first flow path (47A) and the downstream side of the second valve (97B) in the second flow path (47B), the third valve (97C) controlling the emission of the gas from the second nozzle (56B); and (d) a fourth valve (97D) installed in a fourth flow path (47D) connecting the upstream side of the second valve (97B) in the second flow path (47B) and the downstream side of the first valve (97A) in the first flow path (47A), the fourth valve (97D) controlling the emission of the gas from the first nozzle (56A), (e) the gas supply system being configured so that a difference between the average of a conductance of the first valve (97A) and a conductance of the fourth valve (97D) and the average of a conductance of the second valve (97B) and a conductance of the third valve (97C) is smaller than a difference between the conductance of the first valve (97A) and the conductance of the second valve (97B). This configuration provides a gas supply system that can level out a difference in amount between gases emitted from the first nozzle 56A and the second nozzle 56B.

### Method of Processing Substrate

The substrate processing apparatus (1) can be used to perform a method of processing a substrate, including: (a) emitting a gas into a process chamber (2) through a first valve (97A) installed in a first flow path (47A) connecting a gas supply source (72A, 72B) and a first nozzle (56A) that emits the gas into the process chamber (2), the first valve (97A) controlling the emission of the gas from the first nozzle (56A); (b) emitting a gas into the process chamber (2) through a second valve (97B) installed in a second flow path (47B) connecting a gas supply source (72A, 72B) and a second nozzle (56B) that emits the gas into the process chamber (2), the second valve (97B) controlling the emission of the gas from the second nozzle (56B); (c) emitting a gas into the process chamber (2) through a third valve (97C) installed in a third flow path (47C) connecting the upstream side of the first valve (97A) in the first flow path (47A) and the downstream side of the second valve (97B) in the second flow path (47B), the third valve (97C) controlling the emission of the gas from the second nozzle (56B); and (d) emitting a gas into the process chamber (2) through a fourth valve (97D) installed in a fourth flow path (47D) connecting the upstream side of the second valve (97B) in the second flow path (47B) and the downstream side of the first valve (97A) in the first flow path (47A), the fourth valve (97D) controlling the emission of the gas from the first nozzle (56A), wherein (a) to (d) are performed in a state in which a difference between the average of a conductance of the first valve (97A) and a conductance of the fourth valve (97D) and the average of a conductance of the second valve (97B) and a conductance of the third valve (97C) is smaller than a difference between the conductance of the first valve (97A) and the conductance of the second valve (97B). This method of processing a substrate can level out a difference in amount between gases emitted from the first nozzle 56A and the second nozzle 56B during substrate processing.

### Method of Manufacturing Semiconductor Device

The substrate processing apparatus (1) can be used to perform a method of manufacturing a semiconductor device, including: (a) emitting a gas into a process chamber (2) through a first valve (97A) installed in a first flow path (47A) connecting a gas supply source (72A, 72B) and a first nozzle (56A) that emits the gas into the process chamber (2), the first valve (97A) controlling the emission of the gas from the first nozzle (56A); (b) emitting a gas into the process chamber (2) through a second valve (97B) installed in a second flow path (47B) connecting a gas supply source (72A, 72B) and a second nozzle (56B) that emits the gas into the process chamber (2), the second valve (97B) controlling the emission of the gas from the second nozzle (56B); (c) emitting a gas into the process chamber (2) through a third valve (97C) installed in a third flow path (47C) connecting the upstream side of the first valve (97A) in the first flow path (47A) and the downstream side of the second valve (97B) in the second flow path (47B), the third valve (97C) controlling the emission of the gas from the second nozzle (56B); and (d) emitting a gas into the process chamber (2) through a fourth valve (97D) installed in a fourth flow path (47D) connecting the upstream side of the second valve (97B) in the second flow path (47B) and the downstream side of the first valve (97A) in the first flow path (47A), the fourth valve (97D) controlling the emission of the gas from the first nozzle (56A), wherein (a) to (d) are performed in a state in which a difference between the average of a conductance of the first valve (97A) and a conductance of the fourth valve (97D) and the average of a conductance of the second valve (97B) and a conductance of the third valve (97C) is smaller than a difference between the conductance of the first valve (97A) and the conductance of the second valve (97B). This method of manufacturing a semiconductor device can level out a difference in amount between gases emitted from the first nozzle 56A and the second nozzle 56B during the manufacturing of the semiconductor device by processing the substrate 31.

### Program

The above-described method of processing a substrate or method of manufacturing a semiconductor device can be realized by a program that causes, by a computer, a substrate processing apparatus (1) to perform a process including: (a) emitting a gas into a process chamber (2) through a first valve (97A) installed in a first flow path (47A) connecting a gas supply source (72A, 72B) and a first nozzle (56A) that emits the gas into the process chamber (2), the first valve (97A) controlling the emission of the gas from the first nozzle (56A); (b) emitting a gas into the process chamber (2) through a second valve (97B) installed in a second flow path (47B) connecting a gas supply source (72A, 72B) and a second nozzle (56B) that emits the gas into the process chamber (2), the second valve (97B) controlling the emission of the gas from the second nozzle (56B); (c) emitting a gas into the process chamber (2) through a third valve (97C) installed in a third flow path (47C) connecting the upstream side of the first valve (97A) in the first flow path (47A) and the downstream side of the second valve (97B) in the second flow path (47B), the third valve (97C) controlling the emission of the gas from the second nozzle (56B); and (d) emitting a gas into the process chamber (2) through a fourth valve (97D) installed in a fourth flow path (47D) connecting the upstream side of the second valve (97B) in the second flow path (47B) and the downstream side of the first valve (97A) in the first flow path (47A), the fourth valve (97D) controlling the emission of the gas from the first nozzle (56A), wherein (a) to (d) are performed in a state in which a difference between the average of a conductance of the first valve (97A) and a conductance of the fourth valve (97D) and the average of a conductance of the second valve (97B) and a conductance of the third valve (97C) is smaller than a difference between the conductance of the first valve (97A) and the conductance of the second valve (97B). The program can level out a difference in amount between gases emitted from the first nozzle 56A and the second nozzle 56B during the substrate processing by the substrate processing apparatus 1.

### Other Embodiments

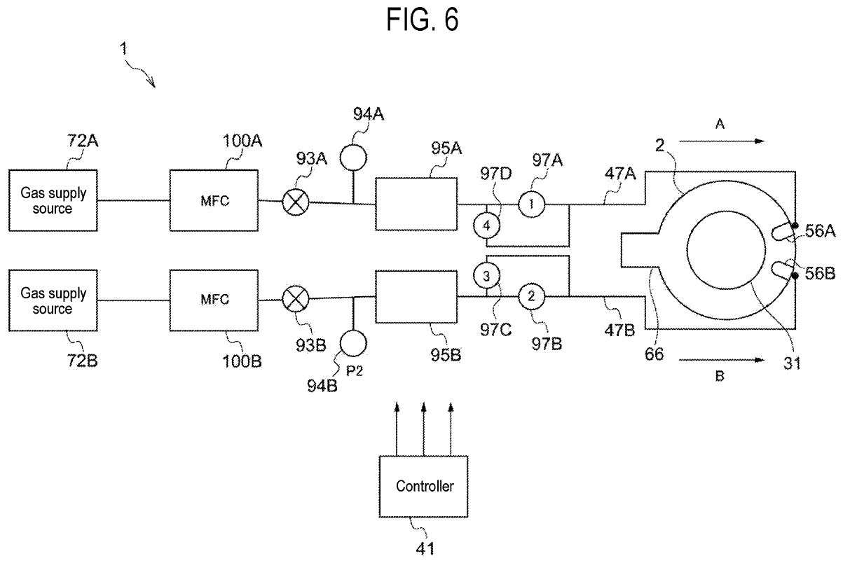

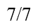

The above-described embodiment can be modified as shown in FIG. 6. That is, another embodiment shown in FIG. 6 is different from the above-described embodiment in that the fourth valve 97D is installed to control fluid communication to the first nozzle 56A by bypassing the first valve 97A from the upstream side of the first valve 97A in the first flow path 47A and that the third valve 97C is installed to control fluid communication to the second nozzle 56B by bypassing the second valve 97B from the upstream side of the second valve 97B in the second flow path 47B. The remaining configurations are the same as those of the above-described embodiment. Even in this embodiment, as long as the difference between the average of a conductance of the first valve 97A and a conductance of the fourth valve 97D and the average of a conductance of the second valve 97B and a conductance of the third valve 97C can be set to be smaller than the difference between the conductance of the first valve 97A and the conductance of the second valve 97B, the difference in amount between gases emitted from the first nozzle 56A and the second nozzle 56B can be leveled out, as in the above-described embodiment.

### Modifications

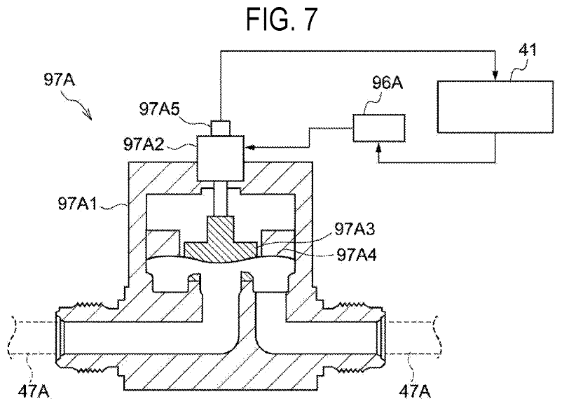

FIG. 7 shows a schematic cross-sectional view of a modified valve structure. Note that FIG. 7 shows the structure of the first valve 97A as a representative example, but the second valve 97B has the same structure.

The first valve 97A is installed in the middle of the first flow path 47A, and includes, in a housing 97A1, a diaphragm 97A4 that reversibly closes a flow path, a valve body 97A3 as a plunger that moves the diaphragm 97A4 up and down, and an actuator 97A2 that moves the valve body 97A3 up and down. The actuator 97A2 is configured so that the position of the valve body 97A3 when opened can be electrically fine-tuned by the controller 41. The opening/closing of the valve body 97A3 may be performed by the actuator 97A2, or by a piston which is provided separately to be driven by a working fluid controlled by the solenoid valve 92A. The above structure is the same as that of the above-described embodiment.

In this modification, the actuator 97A2 is installed with a position sensor 97A5 that is coaxial with the valve body 97A3. The position sensor 97A5 detects the position of the valve body 97A3 and converts the detected position into a value. That is, the first valve 97A and the second valve 97B each include the position sensor 97A5 that detects the position of the valve body 97A3, and the controller 41 is configured to be able to read the value of the position sensor 97A5.

The conductance of the first valve 97A or the second valve 97B may change over time with repeated use, and if it deviates from a preset value, there is a possibility that the amount of gas emitted from each nozzle in the substrate processing apparatus 1 may vary. In such a case, the position sensor 97A5 detects the amount of change in the position of the valve body 97A3 and feeds the detected amount of change back to the controller 41, so that the drive amount of the actuator 97A2 can be corrected through the solenoid valve 96A.

### Others

The embodiments of the present disclosure are specifically described in the above, but the present disclosure is not limited to the above-described embodiments and can be modified in various ways without departing from the spirit of the present disclosure.

Note that the above-described embodiment does not limit the specific mode of substrate processing, but the present disclosure can be suitably applied to a case where a batch-type substrate processing apparatus that processes a plurality of substrates at a time is used to process the substrates, as well as to a case where a single-wafer type substrate processing apparatus that processes one or several substrates at a time is used to process the one or several substrates. Furthermore, the present disclosure can be suitably applied to a case where a substrate processing apparatus having a hot-wall type process furnace is used to process a substrate, and also to a case where a substrate processing apparatus having a cold-wall type process furnace is used to process a substrate.

Even when using these substrate processing apparatuses, each process can be performed using the same processing procedures and process conditions as in the above-described embodiments and modifications, and the same effects as in the above-described embodiments and modifications can be obtained.

The above-described embodiments and modifications can be used in proper combination. The processing procedures and process conditions at this time can be, for example, the same as the processing procedures and process conditions of the above-described embodiments and modifications.

According to the present disclosure in some embodiments, it is possible to eliminate uneven gas supply caused by differences in the conductances of valves installed in a plurality of pipe systems.

While certain embodiments are described, these embodiments are presented by way of example, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus comprising:
a first valve installed in a first flow path connecting a first gas supply source and a first nozzle that emits a gas into a process chamber, the first valve controlling the emission of the gas from the first nozzle;
a second valve installed in a second flow path connecting a second gas supply source and a second nozzle that emits a gas into the process chamber, the second valve controlling the emission of the gas from the second nozzle;
a third valve installed in a third flow path connecting an upstream side of the first valve in the first flow path and a downstream side of the second valve in the second flow path, the third valve controlling the emission of the gas from the second nozzle; and
a fourth valve installed in a fourth flow path connecting an upstream side of the second valve in the second flow path and a downstream side of the first valve in the first flow path, the fourth valve controlling the emission of the gas from the first nozzle,
wherein the substrate processing apparatus is configured so that a difference between the average of a conductance of the first valve and a conductance of the fourth valve and the average of a conductance of the second valve and a conductance of the third valve is smaller than a difference between the conductance of the first valve and the conductance of the second valve.

2. The substrate processing apparatus of claim 1, wherein at least one selected from the group of a set of the first valve and the second valve and a set of the third valve and the fourth valve is an opening/closing valve.

3. The substrate processing apparatus of claim 1, wherein at least one selected from the group of a set of the first valve and the second valve and a set of the third valve and the fourth valve is a conductance valve, and each of the conductances of the valves is a conductance when the conductance valve is fully opened.

4. The substrate processing apparatus of claim 1, wherein the first valve to the fourth valve are installed at the most downstream position among a plurality of valves installed between any gas supply source and the first and second nozzles.

5. The substrate processing apparatus of claim 1, further comprising:
a first buffer tank installed on an upstream side of a branch point of the first flow path to the third valve; and
a second buffer tank installed on an upstream side of a branch point of the second flow path to the fourth valve.

6. The substrate processing apparatus of claim 1, wherein the third flow path and the fourth flow path have substantially equal conductance and are arranged to intersect three-dimensionally.

7. The substrate processing apparatus of claim 5, further comprising:
a controller configured to be capable of controlling the first valve and the third valve to be alternatively opened when a predetermined amount of gas is accumulated in the first buffer tank, and the second valve and the fourth valve to be alternatively opened when a predetermined amount of gas is accumulated in the second buffer tank.

8. The substrate processing apparatus of claim 1, further comprising:
a controller configured to be capable of controlling the first valve and the fourth valve to be opened alternatively and the second valve and the third valve to be opened alternatively.

9. The substrate processing apparatus of claim 8, wherein the conductance of the first valve is greater than an arithmetic mean of the conductances from the first valve to the fourth valve, and the conductance of the fourth valve is smaller than the arithmetic mean.

10. The substrate processing apparatus of claim 9, wherein the conductance of one of the second valve and the third valve is greater than the arithmetic mean, and the conductance of the other is smaller than the arithmetic mean.

11. The substrate processing apparatus of claim 8, wherein a ratio of the frequency at which the first valve is opened to a frequency at which the fourth valve is opened is set as an integer ratio that approximates a ratio of the absolute value of a deviation in the conductance of the fourth valve to the absolute value of a deviation in the conductance of the first valve.

12. The substrate processing apparatus of claim 8, wherein the first valve and the fourth valve are selected from among four or more valves including the first valve to the fourth valve such that the fourth valve has a conductance closest to a value obtained by inverting the sign of the deviation of the conductance of the first valve, and
wherein the second valve and the third valve are selected from among the four or more valves excluding the first valve and the fourth valve such that the third valve has a conductance closest to a value obtained by inverting the sign of the deviation of the conductance of the second valve.

13. The substrate processing apparatus of claim 8, wherein the controller is configured to be capable of controlling the first valve and the fourth valve to be alternately opened and the second valve and the third valve to be alternately opened.

14. The substrate processing apparatus of claim 8, wherein the first valve to the fourth valve are pneumatic valves, the first valve and the second valve are configured to be opened/closed in conjunction with each other, and the third valve and the fourth valve are opened/closed in conjunction with each other.

15. The substrate processing apparatus of claim 8, wherein a difference between the reciprocal of a combined conductance of the first valve and the fourth valve and the reciprocal of a combined conductance of the second valve and the third valve is set so as to compensate for a difference between the reciprocal of the conductance of the second flow path and the reciprocal of the conductance of the first flow path.

16. The substrate processing apparatus of claim 8, wherein the first valve and the second valve each comprises a position sensor that detects the position of a valve body, and the controller is configured to be capable of reading a value of the position sensor.

17. A gas supply system comprising:
a first valve installed in a first flow path connecting a first gas supply source and a first nozzle that emits a gas into a process chamber, the first valve controlling the emission of the gas from the first nozzle;
a second valve installed in a second flow path connecting a second gas supply source and a second nozzle that emits a gas into the process chamber, the second valve controlling the emission of the gas from the second nozzle;
a third valve installed in a third flow path connecting an upstream side of the first valve in the first flow path and a downstream side of the second valve in the second flow path, the third valve controlling the emission of the gas from the second nozzle; and
a fourth valve installed in a fourth flow path connecting an upstream side of the second valve in the second flow path and a downstream side of the first valve in the first flow path, the fourth valve controlling the emission of the gas from the first nozzle,
wherein the gas supply system is configured so that a difference between the average of a conductance of the first valve and a conductance of the fourth valve and the average of a conductance of the second valve and a conductance of the third valve is smaller than a difference between the conductance of the first valve and the conductance of the second valve.

18. A method of processing a substrate, comprising:
(a) emitting a gas into a process chamber through a first valve installed in a first flow path connecting a first gas supply source and a first nozzle that emits the gas into the process chamber, the first valve controlling the emission of the gas from the first nozzle;
(b) emitting a gas into the process chamber through a second valve installed in a second flow path connecting a second gas supply source and a second nozzle that emits the gas into the process chamber, the second valve controlling the emission of the gas from the second nozzle;
(c) emitting a gas into the process chamber through a third valve installed in a third flow path connecting an upstream side of the first valve in the first flow path and a downstream side of the second valve in the second flow path, the third valve controlling the emission of the gas from the second nozzle; and
(d) emitting a gas into the process chamber through a fourth valve installed in a fourth flow path connecting an upstream side of the second valve in the second flow path and a downstream side of the first valve in the first flow path, the fourth valve controlling the emission of the gas from the first nozzle,
wherein (a) to (d) are performed in a state in which a difference between the average of a conductance of the first valve and a conductance of the fourth valve and the average of a conductance of the second valve and a conductance of the third valve is smaller than a difference between the conductance of the first valve and the conductance of the second valve.

19. A method of manufacturing a semiconductor device, comprising: the method of Claim 18.

20. A non-transitory computer-readable recording medium storing a program that causes, by a computer, a substrate processing apparatus to perform a process comprising: the method of claim 18.
